(19) United States
(12) Patent Application Publication
(10) Pub. No.: US 2025/0151226 A1
(43) Pub. Date: May 8, 2025

(54) HEAT DISSIPATION DEVICE AND COMPUTER DEVICE

(71) Applicant: Fulian Precision Electronics (Tianjin) Co., LTD., Tianjin (CN)

(72) Inventors: PAO-CHING WANG, New Taipei (TW); WEN-CHEN WANG, New Taipei (TW)

(21) Appl. No.: 18/938,466

(22) Filed: Nov. 6, 2024

(30) Foreign Application Priority Data
Nov. 7, 2023 (CN) 202311478830.0

(51) Int. Cl. H05K 7/20

(52) U.S. Cl. CPC H05K 7/20172; H05K 7/20145

(57) ABSTRACT

A heat dissipation device and a computer device are disclosed. The heat dissipation device includes a case and a fan module. The case includes a first wall, a second wall and an accommodation cavity. The accommodation cavity is located between the first wall and the second wall in a first direction. The first wall includes a first through hole. The second wall includes a second through hole. The first through hole is connected to the accommodation cavity, the second through hole is connected to the accommodation cavity. The fan module is mounted in the accommodation cavity. The fan module includes a bracket assembly and a plurality of fans. The bracket assembly is detachably connected to the plurality of fans and the case.

### FIELD

The present application relates to a technical field of heat dissipation, especially relates to a heat dissipation device and a computer device.

### BACKGROUND

A computer device typically is integrated with a plurality of modules, which generate a large amount of heat during operation. To ensure the computer device's performance, one or a plurality of fans are installed in a chassis of the computer device to form a heat dissipation device for cooling. However, when the size of the fan is changed, a corresponding case needs to be redesigned, which increases the cost of the server.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric, assembled view a heat dissipation device according to an embodiment of the present disclosure.

FIG. 2 is similar to FIG. 1, but viewed in a different aspect.

FIG. 3 is an isometric, assembled view of a fan module of FIG. 1.

FIG. 4 is an exploded view of the heat dissipation device of FIG. 1.

FIG. 5 is an exploded view of the heat dissipation device of FIG. 2.

FIG. 6 is an isometric, exploded view of a heat dissipation device of another embodiment, which includes two fans.

FIG. 7 is an isometric, exploded view of a heat dissipation device of yet another embodiment, which includes three fans.

FIG. 8 is a schematic diagram of a computer device according to another embodiment of the present disclosure.

### DETAILED DESCRIPTION

In order to make the above-mentioned objects, features, and advantages of the present application more obvious, a description of specific embodiments of the present application will be described with reference to the accompanying drawings. The present application can be implemented in many ways different from those described herein, and those skilled in the art can make similar improvements without violating the contents of the present application. Therefore, the present application is not to be considered as limiting the scope of the embodiments to those described herein.

Several definitions that apply throughout this disclosure will now be presented.

Unless otherwise defined, all technical and scientific terms used herein have the same meaning as commonly understood by one skilled in the art. The terms used in the present application herein are only for describing specific embodiments, and are not intended to limit the present application.

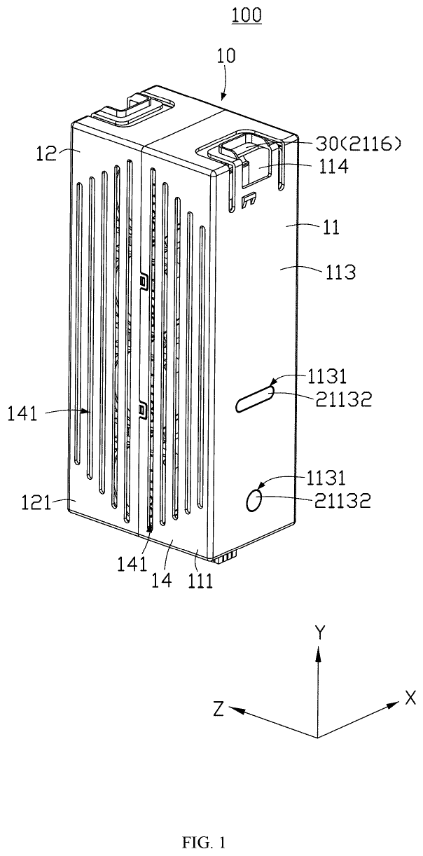

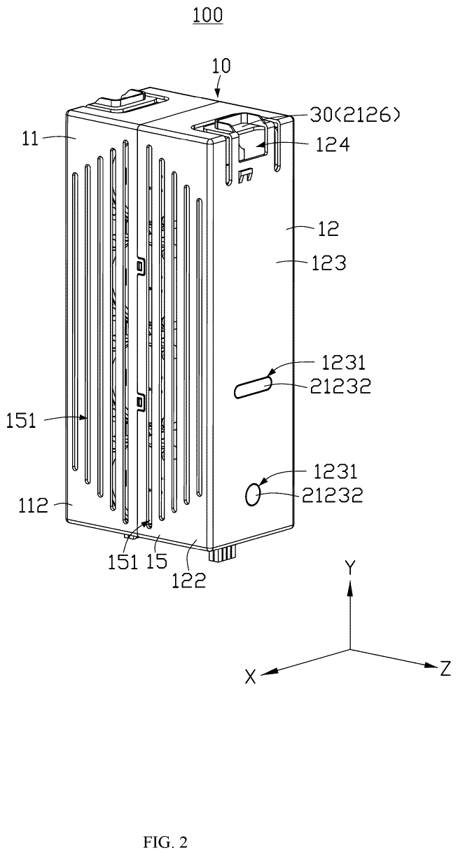

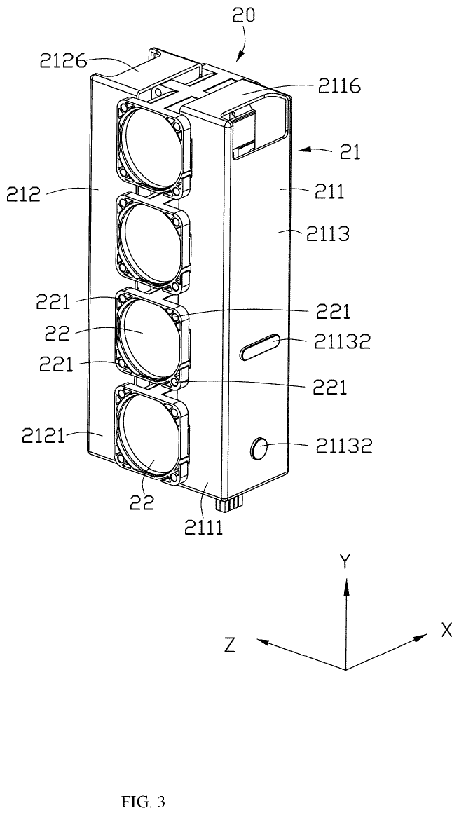

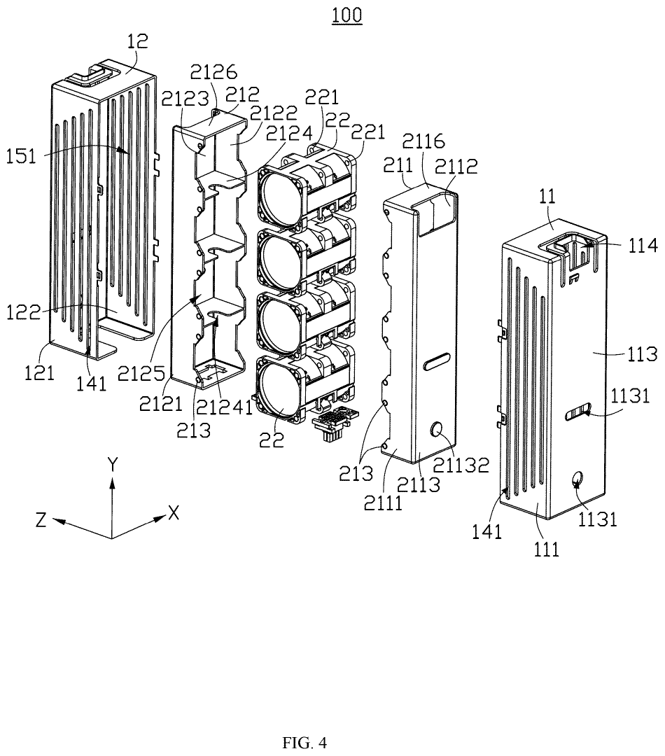

Referring to FIGS. 1-5, in an embodiment, a heat dissipation device 100 is mounted in a chassis of a computer device 200, and is configured for cooling the computer device 200.

The heat dissipation device 100 includes a case 10 and a fan module 20. The fan module 20 is detachably connected to the case 10. The fan module 20 includes a bracket assembly 21 and a plurality of fans 22. The plurality of fans 22 are detachably connected to the bracket assembly 21. The bracket assembly 21 is detachably connected to case 10.

In an embodiment, the locking portion includes a plurality of first protrusions 213, and the positioning portion includes a plurality of first concaves 221.

In an embodiment, each of the plurality of protrusions 213 is engaged in one of the plurality of first concaves 221, that simplifies a processing technology of the first concave 221, and saving the manufacturing cost.

In an embodiment, a plurality of fans 22 are arranged along a second direction Y. The second direction Y and the first direction X are perpendicular to each other.

In an embodiment, the bracket assembly 21 includes a first bracket 211 and a second bracket 212. The first bracket 211 and the second bracket 212 are arranged in a third direction Z. The first bracket 211 is detachably connected to each of the plurality of fans 22. The second bracket 212 is detachably connected to each of the plurality of fans 22. The third direction Z and the first direction X are perpendicular to each other, and the third direction Z and the second direction Y are perpendicular to each other.

In an embodiment, the first bracket 211 includes a first side plate 2111 and a second side plate 2112. The first side plate 2111 and the second side plate 2112 are arranged in the first direction X. The plurality of first protrusions 213 are arranged on the first side plate 2111. The plurality of first protrusions 213 are arranged in the second direction Y. Each of the plurality of first protrusions 213 on the first side plate 2111 is connected to one the plurality of first concaves 221. The plurality of first protrusions 213 are arranged on the second side plate 2112. The plurality of first protrusions 213 are arranged in the second direction Y, each of the plurality of first protrusions 213 on the second side plate 2112 is connected to one of the plurality of first concaves 221.

In an embodiment, the second bracket 212 includes a third side plate 2121 and a fourth side plate 2122. The third side plate 2121 and the fourth side plate 2122 are arranged in the first direction X. The third side plate 2121 includes a plurality of second protrusions. The plurality of second protrusions are arranged in the second direction Y. Each of the plurality of second protrusions on the third side plate 2121 is connected to one of the plurality of first concaves 221. The fourth side plate 2122 includes a plurality of second protrusions, the plurality of second protrusions are arranged in the second direction Y. Each of the plurality of second protrusions on the fourth side plate 2122 is connected to one of the plurality of first concaves 221.

In an embodiment, the first protrusion 213 is connected to the first concave 221 to form a clamping structure, the efficiency of assembling and disassembling the heat dissipation device is improved.

In an embodiment, the first bracket 211 defines a plurality of first grooves 2115. Each of the plurality of first grooves 2115 is recessed in a direction opposite to the third direction. The plurality of first grooves 2115 are arranged in the second direction Y, and the plurality of first grooves are connected to each other. The plurality of first grooves 2115 are configured for accommodating cables of the plurality of fans 22, reducing the influence of the cables on the assembly between the fan module 20 and the case 10.

In an embodiment, the first bracket 211 further includes a first base plate 2113 and a plurality of first baffle plates 2114. The first base plate 2113 is located between the first side plate 2111 and the second side plate 2112. The first base plate 2113 is connected to the first side plate 2111 and the second side plate 2112. The first baffle plate 2114 is located between the first side plate 2111 and the second side plate 2112. The first baffle plate 2114 is connected to the first side plate 2111, the second side plate 2112 and the first base plate 2113. The plurality of first baffle plates 2114 are arranged in the second direction Y. The first side plate 2111, the second side plate 2112, the first base plate 2113 and the plurality of first baffle plates 2114 are connected to form the plurality of first grooves 2115. The first baffle plate 2114 is located between two adjacent first grooves 2115.

The end of the first baffle plate 2114, away from the first base plate 2113, has a first notch 21141. The first notch 21141 is connected to the two adjacent first grooves 2115, so that all the first grooves 2115 are connected to each other, and the cables can pass through the plurality of first baffle plates 2114, thereby improving the convenience of wiring.

In an embodiment, the second bracket 212 defines a plurality of second groove 2125. Each of the plurality of second groove 2125 is recessed in the second direction Y. The plurality of second grooves 2125 are connected to each other. The plurality of second groove 2125 are configured for accommodating the cables of the plurality of fans 22, reducing the influence of the cables on the assembly between the fan module 20 and the case 10.

In an embodiment, the second bracket 212 further includes a second base plate 2123 and a plurality of second baffle plates 2124. The second base plate 2123 is located between the third side plate 2121 and the fourth side plate 2122. The second base plate 2123 is connected to the third side plate 2121 and the fourth side plate 2122. The second baffle plate 2124 is located between the third side plate 2121. The fourth side plate 2122, and the second baffle plate 2124 is connected to the third side plate 2121, fourth side plate 2122 and the second base plate 2123. The plurality of second baffle plates 2124 are arranged in the second direction Y. The third side plate 2121, the fourth side plate 2122, the second base plate 2123 and the plurality of second baffle plates 2124 are connected to form the plurality of second grooves 2125. The second baffle plate 2124 is located between two adjacent second grooves 2125.

The end of the second baffle away from the second base plate 2123 has a second notch 21241. The second notch 21241 is connected to the two adjacent second grooves 2125, so that the cables can pass through the plurality of second grooves 2125, thereby improving the convenience of wiring.

In an embodiment, a configuration of the first bracket 211 may be the same as a configuration of the second bracket 212, so that the first bracket 211 and the second bracket 212 can be interchangeable, thereby improving the efficiency of assembling and disassembling the fan module 20. In addition, the first bracket 211 and the second bracket 212 can be manufactured by the same mold equipment, thereby reducing the manufacturing cost of the heat dissipation device 100.

In an embodiment, the case 10 includes a first shell 11 and a second shell 12. The first shell 11 and the second shell 12 are arranged in a third direction Z. The first shell 11 is detachably connected to the second shell 12, and the first shell 11 is clamped to the second shell 12. The first shell and the second shell 12 are connected to form an accommodation cavity 13. The fan module 20 is mounted in the accommodation cavity. The first shell 11 and the second shell 12 are connected through clamping, thereby ensuring connection stability between the first shell 11 and the second shell 12, and improving the efficiency of assembling and disassembling the heat dissipation device 100.

In an embodiment, the first shell 11 includes a third wall 113, the third wall 113. The first bracket 211 and the second bracket 212 are arranged in the third direction Z.

The third wall 113 defines a third through hole 1131. The first base plate 2113 includes a third protrusion 21132. At least a part of third protrusion 21132 is located in the third through hole 1131, thereby ensuring connection stability between the bracket assembly 21 and the first shell 11, and improving the efficiency of assembling and disassembling the heat dissipation device.

In an embodiment, the third through hole 1131 is a waist hole, the third protrusion 21132 is a waist protrusion, improving connection stability between the first bracket 211 and the first shell 11, and preventing the movement of the fan module 20 and the case 10.

In an embodiment, the third through hole 1131 is a round hole, the third protrusion 21132 is a round protrusion.

In an embodiment, the third wall 113 defines a plurality of third through holes 1131. The first base plate 2113 includes a plurality of third protrusions 21132. Each of the plurality of third through holes 1131 is connected to a respective third protrusion 21132 of the plurality of third protrusions 21132, further improving connection stability between the first bracket 211 and the first shell 11, and preventing the movement of the fan module 20 and the case 10.

In an embodiment, the second shell 12 includes a fourth wall 123. A third wall 113, a first bracket 211, a second bracket 212 and a fourth wall 123 are arranged in the third direction Z.

The fourth wall 123 defines a fourth through hole 1231. The second base plate 2123 includes a fourth protrusion 21232. At least a part of the fourth protrusion 21232 is located in the fourth through hole 1231. The bracket assembly 21 and the second shell 12 are connected through clamping, thereby ensuring connection stability between the bracket assembly 21 and the second shell 12, and improving the efficiency of assembling and disassembling the heat dissipation device 100.

the fourth through hole 1231 is a waist hole, the fourth protrusion 21232 is a waist protrusion, improving connection stability between the second bracket 212 and the second shell 12, and preventing the movement of the fan module 20 and the case 10.

In an embodiment, the fourth through hole is a round hole, the fourth protrusion 21232 is a round protrusion.

In an embodiment, the fourth wall 123 defines a plurality of fourth through holes 1231. The second base plate 2123 includes a plurality of fourth protrusions 21232. Each of the plurality of fourth through hole 1231 is connected to one of the plurality of fourth protrusions 21232, further improving connection stability between the second bracket 212 and the second shell 12, and preventing the movement of the fan module 20 and the case 10.

In an embodiment, the first shell 11 includes a first side wall 111 and a second side wall 112. The first side wall 111 and the second side wall 112 are arranged in the first direction X, and the first side wall 111 and the second side wall 112 are both connected to the third wall 113.

The second shell 12 includes a third side wall 121 and a fourth side wall 122. The third side wall 121 and the fourth side wall 122 are arranged in the first direction X, and the third side wall 121 and the fourth side wall 122 are both connected to the fourth wall 123.

The first side wall 111 is clamped to the third side wall 121, the second side wall 112 is clamped to the fourth side wall 122, improving the efficiency of assembling and disassembling the heat dissipation device 100.

In an embodiment, the first side wall 111 and the third side wall 121 are connected to form the first wall 14 of the case 10. The second side wall 112 and the fourth side wall 122 are connected to form the second wall 15 of the case 10. The first wall 14, the accommodation cavity 13 and the second wall 15 are arranged in the first direction X.

The first wall 14 defines a first through hole 141. The second wall 15 defines a second through hole 151. The first through hole 141 is connected to the accommodation cavity 13. The second through hole 151 is connected to the accommodation cavity 13. In response to the operation of one of the plurality of fans 22, the airflow is driven into the accommodation cavity 13 through the first through-hole 141, and then flows out from the second through-hole 151. Or in response to the operation of one of the plurality of fans 22, the airflow is driven into the accommodation cavity 13 through the second through hole 151, and then flows out from the first through hole 141. It makes the airflow in the chassis of the computer device 200 and has the effect of heat dissipation. Therefore, the effect of heat dissipation is achieved.

In an embodiment, the first wall 14 defines a plurality of first through holes 141. Some of the plurality of first through holes 141 penetrates the first side wall 111, and some penetrate the third side wall 121, thereby facilitating increased airflow through the first wall 14, reducing the influence of the first wall 14 on the airflow generated by the plurality of fans 22, and improving the heat dissipation effect of the heat dissipation device 100.

In an embodiment, the second wall 15 defines a plurality of second through holes 151. Some of the plurality of second through holes 151 penetrates the second side wall 112, and some penetrate the fourth side wall 122, which facilitates airflow through the second wall 15, thereby improving the heat dissipation effect of the heat dissipation device 100.

In an embodiment, the first through hole 141 extends along the second direction Y. The second through hole 151 extends along the second direction Y. The plurality of fans 22 are arranged along the second direction Y, which facilitates airflow through the first wall 14 and the second wall 15, thereby improving the heat dissipation effect of the heat dissipation device 100.

In an embodiment, the heat dissipation device 100 further includes handle 30. The handle 30 is configured for grasping and carrying the heat dissipation device 100, thereby enhancing the convenience of operating the heat dissipation device 100.

In an embodiment, the first bracket 211 includes a first handle 2116. The first shell 11 includes a third notch 114. The first handle 2116 is exposed through the third notch 114, enabling the user's hand to pass through the third notch 114 and grasp the first handle portion 2116.

Compared to transporting the heat dissipation device 100 by grasping the case 10, given that the fan module 20 weighs more than the case 10, there exists a risk of the fan module 20, which is located within the accommodation cavity 13, undergoing relative movement with respect to the case 10 due to gravity or inertia. However, in this embodiment, by transporting the heat dissipation device 100 by directly grasping the fan module 20, reducing the risk of relative movement between the fan module 20 and the case 10.

In an embodiment, the second bracket 212 includes a second handle 2126. The second shell 12 includes a fourth notch 124. The second handle 2126 is exposed through the fourth notch 124, enabling the user's hand to pass through the fourth notch 124 and grasp the second handle 2126, thereby enhancing the convenience of transporting the heat dissipation device 100 and improving safety during the transportation process.

In an embodiment, a structure of the first shell 11 may be the same as a structure of the second shell 12, so that the first shell 11 and the second shell 12 can be interchangeable, thereby improving the efficiency of assembling and disassembling the heat dissipation device 100. In addition, the first shell 11 and the second shell 12 can be manufactured by the same mold equipment, thereby reducing the manufacturing cost of the heat dissipation device 100.

In an embodiment, the first shell 11 is made of plastic material, which helps reduce its weight and minimize the impact of this weight on the computer device 200. Furthermore, the plastic material facilitates slight deformation, enabling a clamped connection with the second shell 12, and improving the convenience of assembling and disassembling the heat dissipation device 100.

In an embodiment, due to the fact that the first shell 11 is formed through the solidification of molten plastic, it allows for a simplified manufacturing process of the first shell 11, thereby enhancing its manufacturing efficiency and reducing its production costs.

In an embodiment, the second shell 12 is made of plastic material, which helps reduce its weight and minimize the impact of its weight on the computer device 200. Furthermore, the plastic material facilitates slight deformation, enabling a clamped connection with the first shell 11, and improving the convenience of assembling and disassembling the heat dissipation device 100.

In an embodiment, the second shell 12 is formed through the solidification of molten plastic, it allows for a simplified manufacturing process of the second shell 12, thereby enhancing its manufacturing efficiency and reducing its production costs.

In an embodiment, the first bracket 211 is made of plastic material, which helps reduce its weight and minimize the impact of its weight on the computer device 200. Furthermore, the plastic material facilitates slight deformation, enabling a clamped connection with the plurality of fans 22, and improving the convenience of assembling and disassembling the fan module 20.

In an embodiment, the first bracket 211 is formed through the solidification of molten plastic, it allows for a simplified manufacturing process of the first bracket 211, thereby enhancing its manufacturing efficiency and reducing its production costs.

In an embodiment, the second bracket 212 is made of plastic material, which helps reduce its weight and minimize the impact of its weight on the computer device 200. Furthermore, the plastic material facilitates slight deformation, enabling a clamped connection with the plurality of fans 22, and improving the convenience of assembling and disassembling the fan module 20.

In an embodiment, the second bracket 212 is formed through the solidification of molten plastic, it allows for a simplified manufacturing process of the second bracket 212, thereby enhancing its manufacturing efficiency and reducing its production costs.

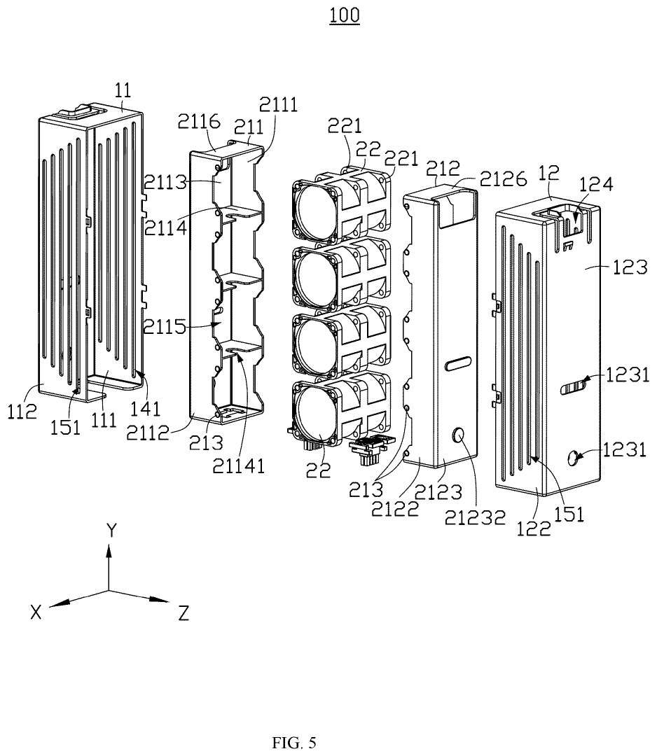

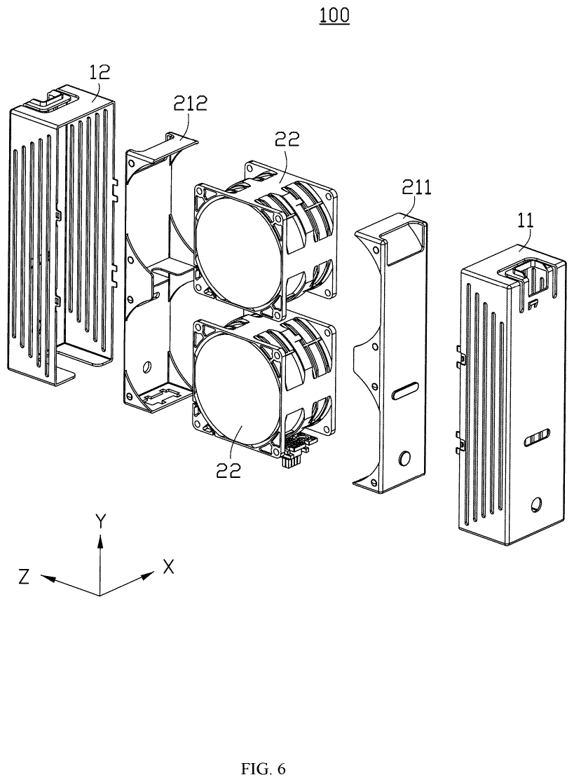

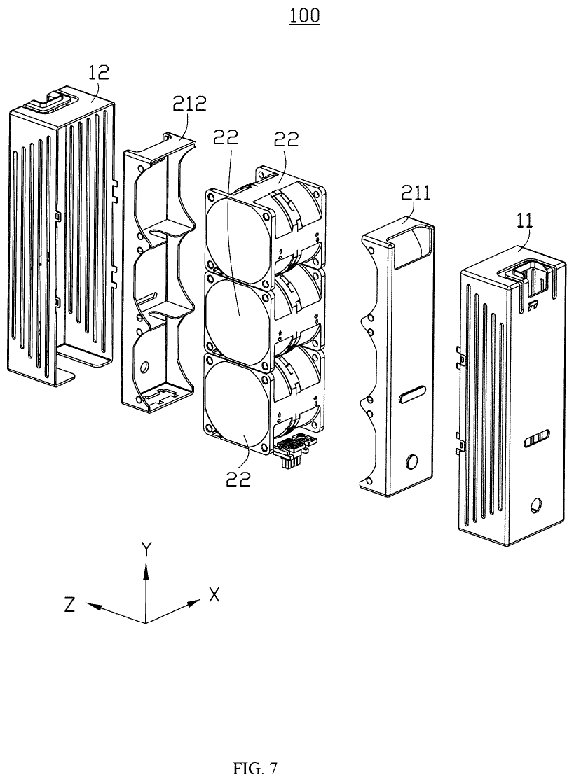

Referring to FIGS. 5-7, in an embodiment, the number of fans 22 can be two, three, four, or even more.

In an embodiment, based on fans of different sizes, corresponding bracket assemblies 21 are designed for matched use. When the plurality of fans 22 needs to be replaced, the case 10 remains unchanged, and only the plurality of fans 22 and the bracket assembly 21 are replaced, reducing the number of components, lowering the manufacturing cost of the heat dissipation device 100 and minimizing the impact of these costs on the computer device 200.

In an embodiment, the bracket assembly 21 includes a first protrusion 213, and each of the plurality of fans 22 includes a first concave 221. At least a part of the first protrusion 213 is engaged with the first concave 221, and the bracket assembly 21 and each of the plurality of fans 22 are detachably connected together. The bracket assembly 21 and each of the plurality of fans 22 are detachable and improve the efficiency of assembling and disassembling the fan module 20.

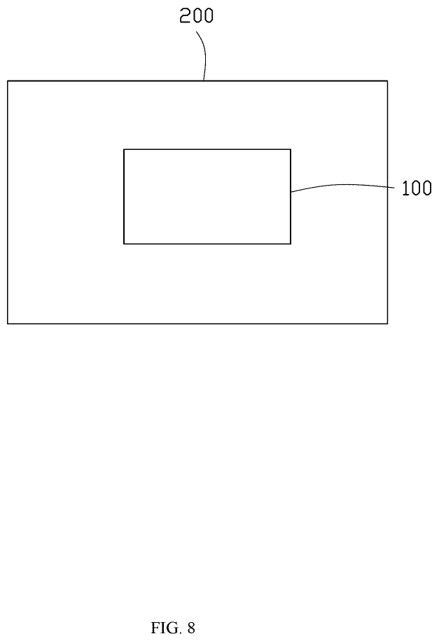

Referring to FIG. 8, in an embodiment, the computer device 200 is disclosed. The computer device 200 includes the heat dissipation device 100. The heat dissipation device 100 is the heat dissipation device 100 in the above-mentioned embodiment. For example, the computer device 200 includes servers, personal computers, workstations, etc.

In an embodiment, the heat dissipation device 100 connects one of the plurality of fans 22 and the case 10 in a detachable manner through the bracket assembly 21. When one of the plurality of fans 22 needs to be replaced, the bracket assembly 21 corresponding to the new fan is used to attach it to the case 10, eliminating the need to replace the case 10. This design allows the case 10 of the heat dissipation device 100 to be compatible with various fan sizes, reducing the number of components, lowering the manufacturing cost of the heat dissipation device 100 and minimizing the impact of these costs on the computer device 200

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure, up to and including the full extent established by the broad general meaning of the terms used in the claims.

What is claimed is:

1. A heat dissipation device comprising:
a case comprising a first wall, a second wall and an accommodation cavity, wherein the accommodation cavity is located between the first wall and the second wall in a first direction, the first wall defines a plurality of first through holes, the second wall defines a plurality of second through holes, each of the plurality of first through holes is connected to the accommodation cavity, each of the plurality of second through holes is connected to the accommodation cavity; and
a fan module mounted in the accommodation cavity, the fan module comprising a bracket assembly and a plurality of fans, wherein the bracket assembly is detachably connected to the plurality of fans, the bracket assembly is detachably connected to the case.

2. The heat dissipation device of claim 1, wherein the bracket assembly defines a first protrusion, and each of the plurality of fans defines a first concave, wherein at least a part of the first protrusion is located in the first concave; or the bracket assembly defines a first concave, and each of the plurality of fans defines a first protrusion, wherein at least a part of the first protrusion is located in the first concave.

3. The heat dissipation device of claim 1, wherein the plurality of fans is arranged in a second direction, the second direction and the first direction are perpendicular to each other;
the bracket assembly comprises a first bracket and a second bracket, the first bracket and the second bracket are arranged in a third direction, the first bracket is detachably connected to each of the plurality of fans, the second bracket is detachably connected to each of the plurality of fans, the third direction and the first direction are perpendicular to each other, and the third direction and the second direction are perpendicular to each other.

4. The heat dissipation device of claim 3, wherein the first bracket defines a plurality of first grooves, each of the plurality of first grooves is recessed in a direction opposite to the third direction, the plurality of first grooves are arranged in the second direction and connected to each other, wherein the plurality of first grooves are configured for accommodating cables of the plurality of fans;
the second bracket defines a plurality of second grooves, each of the plurality of second grooves is recessed in the third direction, the plurality of second grooves are arranged in the second direction and are connected to each other, wherein the plurality of second grooves are configured for accommodating the cables of the plurality of fans.

5. The heat dissipation device of claim 3, wherein the case further comprises a third wall and a fourth wall, the third wall and the fourth wall are arranged in the third direction, the third wall and the fourth wall are respectively connected to the first wall and the second wall, the third wall defines a third through hole, the fourth wall defines a fourth through hole;
the first bracket comprises a third protrusion, wherein at least a part of the third protrusion is located in the third through hole;
the second bracket comprises a fourth protrusion, wherein at least a part of the fourth protrusion is located in the fourth through hole.

6. The heat dissipation device of claim 1, wherein the case further comprises a first shell and a second shell, the first shell and the second shell are arranged in a third direction, the third direction and the first direction are perpendicular to each other;
the first shell comprises a first side wall and a second side wall, the first side wall and the second side wall are arranged in the first direction;
the second shell comprises a third side wall and a fourth side wall, the third side wall and the fourth side wall are arranged in the first direction;
the first side wall and the third side wall are clamped to form the first wall;
the second side wall and the fourth side wall are clamped to form the second wall.

7. A computer device comprising:
a heat dissipation device, the heat dissipation device comprising:
a case comprising a first wall, a second wall and an accommodation cavity, wherein the accommodation cavity is located between the first wall and the second wall in a first direction, the first wall defines a plurality of first through holes, the second wall defines a plurality of second through holes, each of the plurality of first through holes is connected to the accommodation cavity, each of the plurality of second through holes is connected to the accommodation cavity; and
a fan module, mounted in the accommodation cavity, the fan module comprising a bracket assembly and a plurality of fans, wherein the bracket assembly is detachably connected to the plurality of fans, the bracket assembly is detachably connected to the case.

8. The heat dissipation device of claim 7, wherein the bracket assembly defines a first protrusion, and each of the plurality of fans defines a first concave, wherein at least a part of the first protrusion is located in the first concave; or the bracket assembly defines a first concave, and each of the plurality of fans defines a first protrusion, wherein at least a part of the first protrusion is located in the first concave.

9. The heat dissipation device of claim 7, wherein the plurality of fans are arranged in a second direction, the second direction and the first direction are perpendicular to each other;
the bracket assembly comprises a first bracket and a second bracket, the first bracket and the second bracket are arranged in a third direction, the first bracket is detachably connected to each of the plurality of fans, the second bracket is detachably connected to each of the plurality of fans, the third direction and the first direction are perpendicular to each other, and the third direction and the second direction are perpendicular to each other.

10. The heat dissipation device of claim 9, wherein the first bracket defines a plurality of first grooves, each of the plurality of first grooves is recessed in a direction opposite to the third direction, the plurality of first grooves are arranged in the second direction and are connected to each other, wherein the plurality of first grooves are configured for accommodating cables of the plurality of fans;
the second bracket defines a plurality of second grooves, each of the plurality of second grooves is recessed in the third direction, the plurality of second grooves are arranged in the second direction and connected to each other, wherein the plurality of second grooves are configured for accommodating the cables of the plurality of fans.

11. The heat dissipation device of claim 9, wherein the case further comprises a third wall and a fourth wall, the third wall and the fourth wall are arranged in the third direction, the third wall and the fourth wall are respectively connected to the first wall and the second wall, the third wall defines a third through hole, the fourth wall defines a fourth through hole;
the first bracket comprises a third protrusion, wherein at least a part of the third protrusion is located in the third through hole;
the second bracket comprises a fourth protrusion, wherein at least a part of the fourth protrusion is located in the fourth through hole.

12. The heat dissipation device of claim 7, wherein the case further comprises a first shell and a second shell, the first shell and the second shell are arranged in a third direction, the third direction and the first direction are perpendicular to each other;
the first shell comprises a first side wall and a second side wall, the first side wall and the second side wall are arranged in the first direction;
the second shell comprises a third side wall and a fourth side wall, the third side wall and the fourth side wall are arranged in the first direction;
the first side wall and the third side wall are clamped to form the first wall;
the second side wall and the fourth side wall are clamped to form the second wall.

13. A computer device comprising:
a case comprising a first shell and a second shell, wherein the first shell and the second shell are clamped to form an accommodation cavity; and
a fan module mounted in the accommodation cavity, the fan module comprising a bracket assembly and a plurality of fans, the bracket assembly comprising a first bracket and a second bracket, wherein the first bracket is detachably connected to each of the plurality of fans, the second bracket is detachably connected to each of the plurality of fans, the first shell is detachably connected to the first bracket, the second shell is detachably connected to the second bracket.

14. The computer device of claim 13, wherein the case comprises a first wall and a second wall, the accommodation cavity is located between the first wall and the second wall in a first direction, the first wall defines a plurality of first through holes, the second wall defines a plurality of second through holes, each of the plurality of first through holes connected to the accommodation cavity, each of the plurality of second through holes connected to the accommodation cavity.

15. The computer device of claim 13, wherein the bracket assembly defines a first protrusion, and each of the plurality of fans defines a first concave, wherein at least a part of the first protrusion is located in the first concave; or the bracket assembly defines a first concave, and each of the plurality of fans defines a first protrusion, wherein at least a part of the first protrusion is located in the first concave.

16. The computer device of claim 13, wherein the plurality of fans are arranged along a second direction, the second direction and the first direction are perpendicular to each other;
the first bracket and the second bracket are arranged along a third direction, the third direction and the first direction are perpendicular to each other, and the third direction and the second direction are perpendicular to each other.

17. The computer device of claim 16, wherein the first bracket defines a plurality of first grooves, each of the plurality of first grooves is recessed in a direction opposite to the third direction, the plurality of first grooves are arranged in the second direction and are connected to each other, wherein the plurality of first grooves are configured for accommodating a cables of the plurality of fans;
the second bracket defines a plurality of second grooves, each of the plurality of second grooves is recessed in the third direction, the plurality of second grooves are arranged in the second direction and connected to each other, wherein the plurality of second grooves are configured for accommodating the cables of the plurality of fans.

18. The computer device of claim 14, wherein the case further comprises a third wall and a fourth wall, the third wall and the fourth wall are arranged in the third direction, the third wall and the fourth wall are respectively connected to the first wall and the second wall, the third wall defines a third through hole, the fourth wall defines a fourth through hole;
the first bracket comprises a third protrusion, wherein at least a part of the third protrusion is located in the third through hole;
the second bracket comprises a fourth protrusion, wherein at least a part of the fourth protrusion is located in the fourth through hole.

19. The computer device of claim 13, wherein the first shell and the second shell are arranged in a third direction, the third direction and the first direction are perpendicular to each other;
the first shell comprises a first side wall and a second side wall, the first side wall and the second side wall are arranged in the first direction;
the second shell comprises a third side wall and a fourth side wall, the third side wall and the fourth side wall are arranged in the first direction;
the first side wall and the third side wall are clamped to form the first wall;
the second side wall and the fourth side wall are clamped to form the second wall.
